(19) United States
(12) Patent Application Publication
(10) Pub. No.: US 2007/0211539 A1
(43) Pub. Date: Sep. 13, 2007

(54) METHOD FOR RESETTING THRESHOLD VOLTAGE OF NON-VOLATILE MEMORY

(75) Inventors: Chih-Kai Kang, Tainan County (TW); Hann-Ping Hwang, Hsinchu City (TW); Chih-Ming Chao, Hsinchu City (TW); Shi-Hsien Cheng, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: POWERCHIP SEMICONDUCTOR CORP., Hsinchu (TW)

(21) Appl. No.: 11/531,682

(22) Filed: Sep. 13, 2006

(30) Foreign Application Priority Data
Mar. 9, 2006 (TW) 95107891

(51) Int. Cl. G11C 16/04; G11C 11/34

(52) U.S. Cl. 365/185.29

(57) ABSTRACT

A method for resetting threshold voltage of a non-volatile memory is provided. The method is suitable for a non-volatile memory having a plurality of memory cells. Each memory cell includes a gate and a charge trapping layer. The method includes erasing the non-volatile memory by Fowler-Nordheim (FN) tunneling effect until erasure saturation. The non-volatile memory has a uniform saturation threshold voltage.

### CROSS-REFERENCE TO RELATED APPLICATION

This application claims the priority benefit of Taiwan application serial no. 95107891, filed Mar. 9, 2006. All disclosure of the Taiwan application is incorporated herein by reference.

### BACKGROUND OF THE INVENTION

1. Field of the Invention

The present invention relates to a method of operating a non-volatile memory, and more particularly, to a method for resetting the threshold voltage of a non-volatile memory.

2. Description of Related Art

Among various memory products, non-volatile memory is capable of storing, reading, or erasing data several times, and the data stored therein will not disappear even after power supply to the memory is cut off, and thus it is broadly used in personal computers and electronic equipment.

A typical electrically erasable and programmable read only memory has a floating gate and control gate manufactured by using doped polysilicon. However, when there are defects in the tunneling oxide layer below the doped polysilicon floating gate layer, current leakage of the devices easily occurs, thus affecting the reliability of the devices.

Therefore, in conventional technology, the charge trapping layer is used to replace the polysilicon floating gate. The material of the charge trapping layer is, for example, silicon nitride. This silicon nitride charge trapping layer usually has a silicon oxide layer respectively disposed above and below it to form an oxide-nitride-oxide (ONO) composite layer. This memory is usually referred to as a silicon-oxide-nitride-oxide-silicon (SONOS) device. Since silicon nitride has the property of trapping electrons, the electrons injected into the charge trapping layer may concentrate in a portion of the charge trapping layer. Therefore, the sensitivity to the defect in the tunneling oxide layer is small, and the current leakage phenomenon of the device will not occur easily.

However, in the general SONOS memory, the substrate generates electrons and holes with the use of, for example, plasma and the like due to the influence of the process environment, and a part of the generated electrons may be stored in the silicon nitride charge trapping layer. Moreover, the amount of electrons stored in the silicon nitride charge trapping layer is not uniform, which causes the non-uniformity in the threshold voltage of each memory cell such that the memory has a relatively large threshold voltage distribution, thus resulting in usage difficulty.

### SUMMARY OF THE INVENTION

An object of the present invention is to provide a method for resetting the threshold voltage of a non-volatile memory, which makes the non-volatile memory have a uniform threshold voltage.

Another object of the present invention is to provide a method for resetting the threshold voltage of a non-volatile memory, which sets the non-volatile memory in a simple way and makes the non-volatile memory have a desired threshold voltage.

The present invention provides a method for resetting threshold voltage of a non-volatile memory, which is suitable for a non-volatile memory having a plurality of memory cells. Each memory cell is disposed on a substrate and includes a gate and a charge trapping layer. The method includes erasing the non-volatile memory by Fowler-Nordheim (FN) tunneling effect until erasure saturation, such that the memory cells have the saturation threshold voltage.

In the above method for resetting threshold voltage of the non-volatile memory, the step of erasing the non-volatile memory by FN tunneling effect is, for example, applying a first voltage to the gates and applying a second voltage to the substrate. The voltage difference between the second voltage and the first voltage is large enough to induce FN tunneling effect.

In the above method for resetting threshold voltage of the non-volatile memory, the voltage difference is about 8 volts to 20 volts.

In the above method for resetting threshold voltage of the non-volatile memory, the first voltage is a negative voltage, and the second voltage is a positive voltage.

In the above method for resetting threshold voltage of the non-volatile memory, the threshold voltage is further determined according to the voltage difference.

The present invention further provides a method for resetting threshold voltage of a non-volatile memory, which is suitable for a non-volatile memory having a plurality of memory cells. Each memory cell is disposed on a substrate and has a gate and a charge trapping layer. The method includes the following steps. (a) First, the threshold voltages and uniformity thereof of the non-volatile memory are detected. (b) Whether or not the threshold voltages and the threshold voltage uniformity of the non-volatile memory are in the range of a target value is determined. (c) When the threshold voltages and the threshold voltage uniformity of the non-volatile memory are not in the range of the target value, a resetting step is performed, and the non-volatile memory is erased by FN tunneling effect until erasure saturation.

In the above method for resetting threshold voltage of the non-volatile memory, the step of erasing the non-volatile memory by FN tunneling effect includes, for example, applying a first voltage to the gate and applying a second voltage to the substrate. The voltage difference between the second voltage and the first voltage is large enough to induce FN tunneling effect.

In the above method for resetting threshold voltage of the non-volatile memory, the voltage difference is about 8 volts to 20 volts.

In the above method for resetting threshold voltage of the non-volatile memory, the first voltage is a negative voltage, and the second voltage is a positive voltage.

In the above method for resetting threshold voltage of the non-volatile memory, the voltage difference is determined according to the target value.

In the above method for resetting threshold voltage of the non-volatile memory, steps (b) to (c) are repeated until the threshold voltage and the threshold voltage uniformity of the non-volatile memory are in the range of the target value.

The present invention provides a method for resetting threshold voltage of a non-volatile memory, which is suitable for a non-volatile memory having a plurality of memory cells. Each memory cell is disposed on a substrate and has a gate and a charge trapping layer. The method includes the following steps. First, the target value of the threshold voltage of the non-volatile memory is set. Then, a voltage difference required to erase the non-volatile memory by FN tunneling effect to the target value of the threshold voltage is determined. The voltage difference is applied between the substrate and the gates to erase the non-volatile memory by FN tunneling effect until erasure saturation, so as to adjust the threshold voltage of the non-volatile memory to the target value of the threshold voltage.

In the above method for resetting threshold voltage of the non-volatile memory, the voltage difference is about 8 volts to 20 volts.

In the above method for resetting threshold voltage of the non-volatile memory, the step of applying the voltage difference between the substrate and the gate includes the following steps. First, the first voltage to be applied to the gate and the second voltage to be applied to the substrate are determined according to the voltage difference. Next, the first voltage is applied to the gate, and the second voltage is applied to the substrate.

In the above method for resetting threshold voltage of the non-volatile memory, the first voltage is a negative voltage, and the second voltage is a positive voltage.

The method for resetting threshold voltage of the non-volatile memory of the present invention is simple and the threshold voltage distribution of the non-volatile memory is reduced easily.

The method for resetting threshold voltage of the non-volatile memory of the present invention controls the reset target value of the threshold voltage accurately and is capable of solving the problem of the non-uniformity of the threshold voltage of each memory cell resulting from the electrons stored in the charge trapping layer caused by the plasma in the process.

The method for resetting threshold voltage of the non-volatile memory of the present invention effectively controls the threshold voltage and the threshold voltage distribution of the non-volatile memory without additional, complicated CMOS circuits.

In order to the make aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a schematic sectional view of a SONOS memory.

FIG. 2 shows a relation diagram of the threshold voltage and the erasing time of a programmed SONOS memory when performing the erasing operation under different erasing biases.

FIG. 3 shows a relation diagram of the threshold voltage and the erasing time of a SONOS memory without being reset, programmed, or erased when performing the resetting operation under different erasing biases.

FIG. 4 shows a relation diagram of the erasing time and the value of 3 times the standard deviation (3σ) when performing the erasing operation under different erasing biases.

FIG. 5 shows a relation diagram of the threshold voltage and the count value when performing the resetting operation (erasing bias=11 volts) for different periods of erasing time.

FIG. 6 shows the flow chart of the steps of the method for resetting the threshold voltage of the non-volatile memory according to an embodiment of the present invention.

FIG. 7 shows the flow chart of the steps of the method for resetting the threshold voltage of the non-volatile memory according to another embodiment of the present invention.

### DESCRIPTION OF EMBODIMENTS

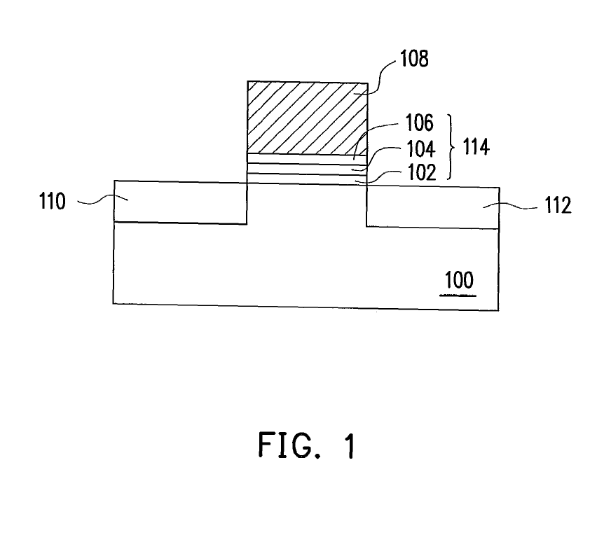

FIG. 1 shows a schematic sectional view of a SONOS memory.

Referring to FIG. 1, the SONOS memory includes, for example, a substrate 100, a bottom dielectric layer 102, a charge trapping layer 104, a top dielectric layer 106, a gate 108, a source region 110, and a drain region 112.

The bottom dielectric layer 102, the charge trapping layer 104, the top dielectric layer 106, and the gate 108 are, for example, sequentially disposed on the substrate 100. The material of the bottom dielectric layer 102 and the top dielectric layer 106 is, for example, silicon oxide. The material of the charge trapping layer 104 is, for example, a charge trapping material, such as silicon nitride. The bottom dielectric layer 102, the charge trapping layer 104 and the top dielectric layer 106, for example, constitute a composite dielectric layer 114. The source region 110 and the drain region 112, for example, are disposed in the substrate 100 on both sides of the gate 108.

When erasing the memory, a voltage difference about 8 volts to 20 volts is applied between the substrate 100 and the gate 108. For example, a voltage of 0 volts is applied to the gate 108, and a voltage of 12 volts is applied to the substrate 100, and electrons are injected into the substrate 100 from the charge trapping layer by Fowler-Nordheim tunneling (FN tunneling) effect. Hereinafter, the erasure voltage difference between the substrate 100 and the gate 108 is referred to as the erasing bias.

Moreover, in FIG. 1, only one single memory cell is illustrated as an example. However, the resetting method of the present invention is suitable for the memory having a plurality of memory cells.

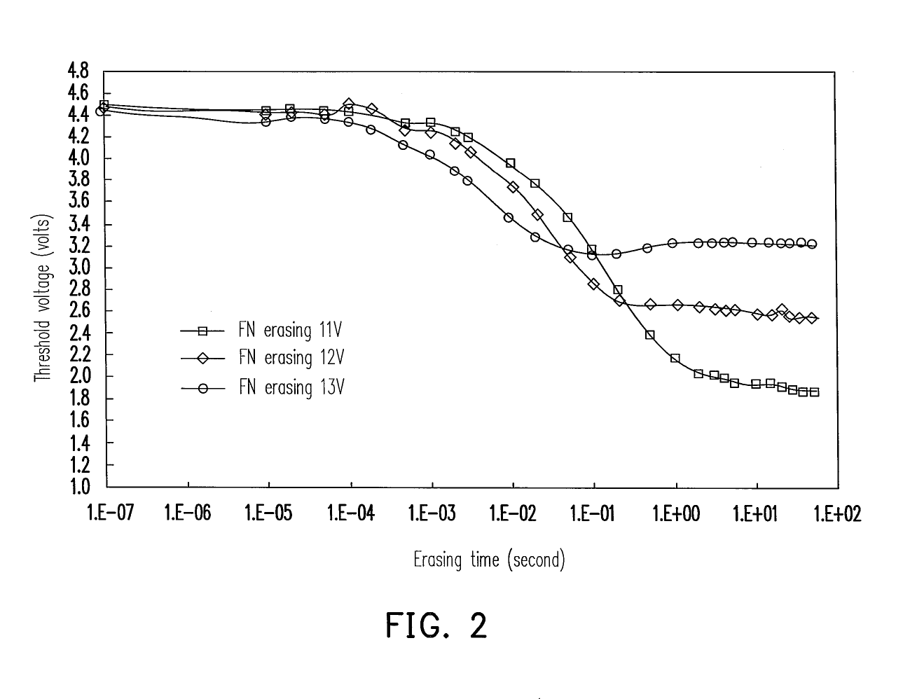

FIG. 2 shows a relation diagram of the threshold voltage and the erasing time of a programmed SONOS memory when performing the erasing operation under different erasing biases. The method for forming different voltage differences between the gate and the substrate includes applying a voltage Vsub (=8 volts) to the substrate and applying different voltages Vg (=−3 volts, −4 volts, or −5 volts) to the gate respectively.

Referring to FIG. 2, after the gate is applied with different voltages Vg (=−3 volts, −4 volts, or −5 volts), it can be found that the threshold voltage gradually approaches a saturation state after erasing operation is performed for a period of time. For example, when the erasing bias is 13 volts, the erasure saturation state is reached after 0.05 and the obtained erasure saturation threshold voltage is about 3.2 volts. When the erasing bias is 12 volts, the erasure saturation state is reached after 0.1 second, and the obtained saturation threshold voltage is about 2.6 volts. When the erasing bias is 11 volts, the erasure saturation state is reached after 1 second, and the obtained saturation threshold voltage is about 2.0 volts. That is because when a voltage Vsub (=8 volts) is applied to the substrate and voltages Vg (=−3 volts, −4 volts, or −5 volts) are applied to the gate respectively, electrons from the gate are injected into the charge trapping layer by the voltage difference between the substrate and the gate, and the threshold voltage is made to gradually represent a saturation state, i.e., the so-called erasure saturation phenomenon. Moreover, the higher the erasing bias is, the higher the saturation threshold voltage is obtained, and the shorter the time is spent in reaching erasure saturation. The present invention employs the erasure saturation phenomenon as the method for accurately setting the threshold voltage.

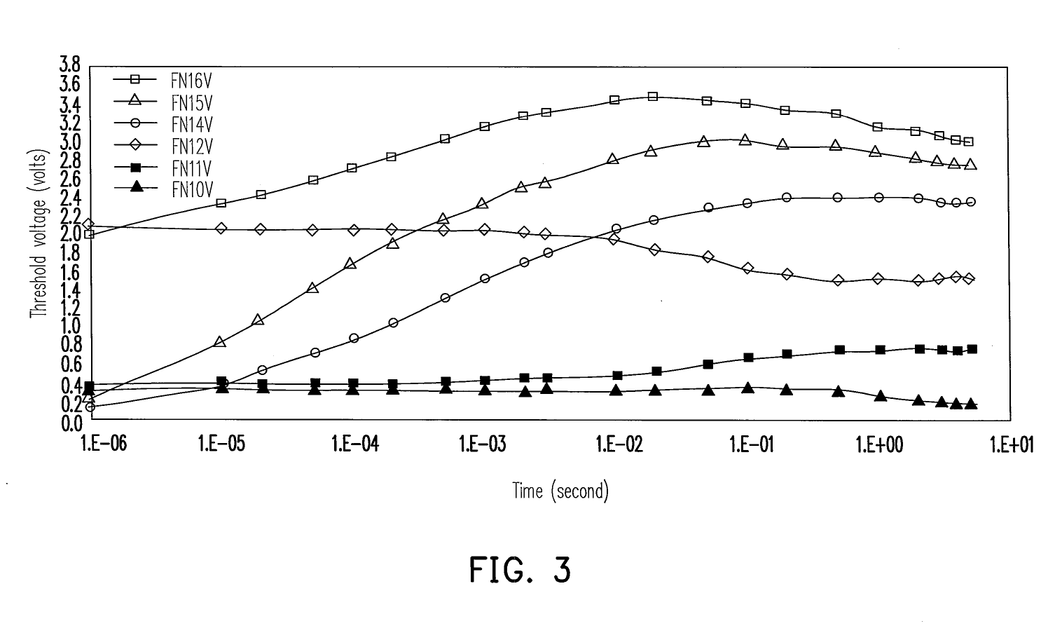

FIG. 3 shows a relationship between the threshold voltage and the erasing time of a SONOS memory without being reset, programmed, or erased when performing the resetting operation under different erasing biases. The method for forming different voltage differences between the substrate and the gate includes applying a voltage Vsub (=8 volts) to the substrate and applying different voltages Vg (=−2 volts, −3 volts, −4 volts, −6 volts, −7 volts, or −8 volts) to the gate respectively.

Referring to FIG. 3, the SONOS memory without being reset, programmed, or erased has different initial threshold voltages distributed randomly. When a voltage Vsub (=8 volts) is applied to the substrate and voltages Vg (=−2 volts, −3 volts, −4 volts, −6 volts, −7 volts, or −8 volts) are respectively applied to the gate for a period of time until reaching erasure saturation, the SONOS memory obtains different saturation threshold voltages under different erasing biases. For example, after the resetting operation has been performed for 5 seconds, when the erasing bias is 16 volts, the obtained saturation threshold voltage is about 3 volts. When the erasing bias is 15 volts, the obtained saturation threshold voltage is about 2.7 volts. When the erasing bias is 14 volts, the obtained saturation threshold voltage is about 2.4 volts. When the erasing bias is 12 volts, the obtained saturation threshold voltage is about 1.5 volts. When the erasing bias is 11 volts, the obtained saturation threshold voltage is about 0.8 volts. When the erasing bias is 10 volts, the obtained saturation threshold voltage is about 0.2 volts.

In FIG. 3, an erasing bias of 16 volts is taken as an example. The initial threshold voltage of the memory is about 2.0 volts. However, after the memory has been erased with an erasing bias of 16 volts for 5 seconds, the obtained saturation threshold voltage is about 3 volts. In another aspect, an erasing bias of 12 volts is taken as an example. The initial threshold voltage of the memory is about 2.1 volts. However, after the memory has been erased with an erasing bias of 12 volts for 5 seconds, the obtained saturation threshold voltage is about 1.5 volts. This result indicates that when resetting is performed on a memory with a specific erasing bias for a period of time, the threshold voltage of the memory is equal to the corresponding saturation threshold voltage of the specific bias regardless of the value of the initial threshold voltage of the memory.

The resetting method of the present invention can be carried out according to the relationship of the threshold voltage and the erasing time in FIG. 3. For example, if it is intended to make the reset memory have a setting threshold voltage, the erasing bias is determined according to the desired setting threshold voltage. That is, if it is intended to make the memory have a threshold voltage of 0.2 volts, the erasing bias is set to 10 volts. Next, the memory is erased with this erasing bias for a period of time until the memory is in the erasure saturation state, and the threshold voltage of the memory is the saturation threshold voltage, i.e., 0.2 volts. As such, if it is intended to make the memory have a threshold voltage of 0.8 volts, the erasing bias is set to 11 volts. The memory is erased with this erasing bias for a period of time until the memory is in the erasure saturation state, and the threshold voltage of the memory is the saturation threshold voltage, i.e., 0.8 volts. Therefore, after the fabrication of the memory and before the shipment thereof, the memory is erased by FN tunneling effect for a period of time with the method for resetting the threshold voltage of the memory of the present invention, until the memory has the saturation threshold voltage and a relatively uniform threshold voltage distribution.

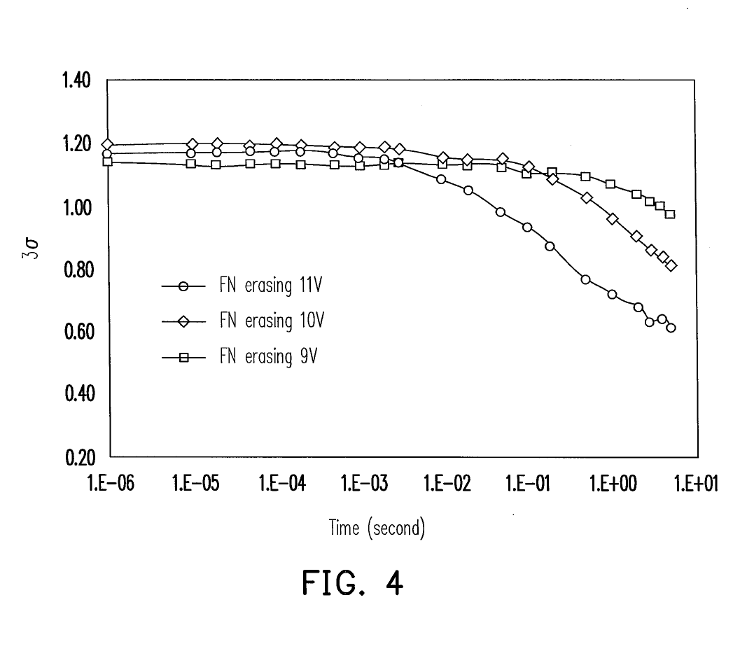

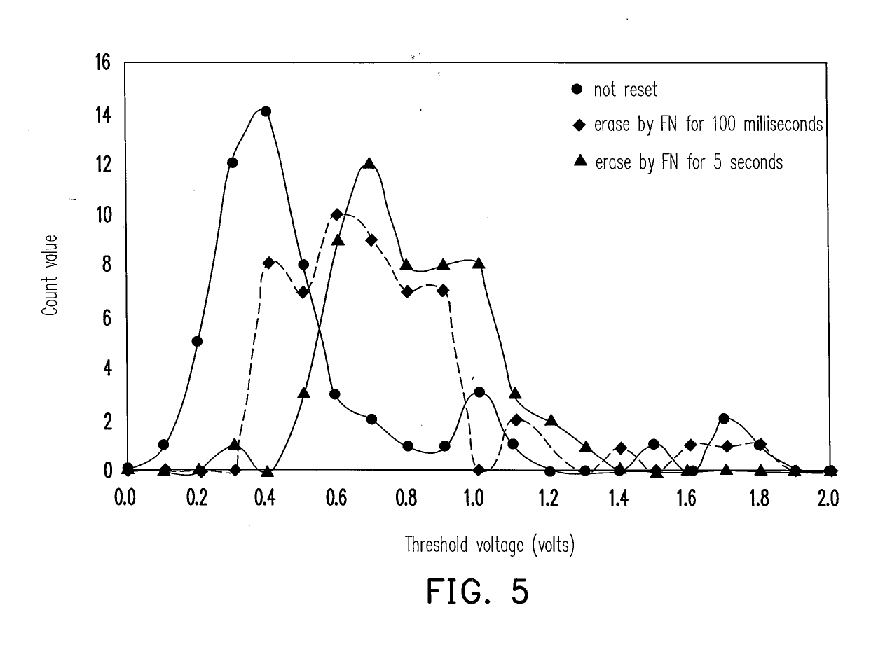

FIG. 4 shows a relationship between the erasing time and the value of 3 times the standard deviation (3σ) when performing the erasing operation under different erasing biases. FIG. 5 shows a relationship between the threshold voltage and the count value when performing the resetting operation (erasing bias=11 volts) for different periods of erasing time.

Referring to FIG. 4, after the resetting operation of the present invention is performed, the value of 3 times the standard deviation (3σ) of the threshold voltage reduces regardless of the value of the erasing bias. For example, after the resetting operation has been performed for 5 seconds, when the erasing bias is 11 volts, the value of 3 times the standard deviation (3σ) of the threshold voltage is reduced from 1.16 to about 0.6. When the erasing bias is 10 volts, the value of 3 times the standard deviation (3σ) of the threshold voltage is reduced from 1.19 to about 0.8. When the erasing bias is 9 volts, the value of 3 times the standard deviation (3σ) of the threshold voltage is reduced from 1.15 to about 0.95. As a result, under the same erasing time, the greater the erasing bias, the more the value of 3 times the standard deviation (3σ) of the threshold voltage is reduced, indicating better uniformity in threshold voltage distribution of the memory.

Moreover, referring to FIG. 5, before the resetting operation is performed, the average threshold voltage of the memory is about 0.39 volts, and the value of 3 times the standard deviation (3σ) is 1.16. After the resetting operation has been performed for 5 seconds, the average threshold voltage of the memory is about 0.83 volts, and the value of 3 times the standard deviation (3σ) is 0.6. From the results of FIG. 4 and FIG. 5, the memory has a relatively uniform threshold voltage distribution by performing the resetting method of the present invention.

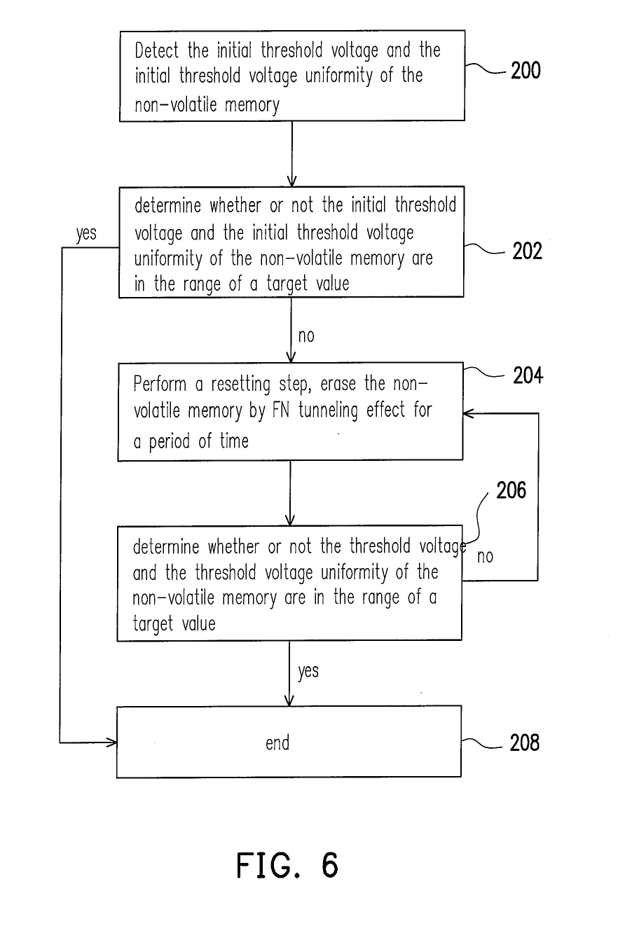

FIG. 6 shows the flow chart of the steps of the method for resetting the threshold voltage of the non-volatile memory according to an embodiment of the present invention.

Referring to FIG. 6, when the fabrication of the memory is completed, each memory cell has a non-uniform threshold voltage under the influence of the process, thus the memory has a relatively large threshold voltage distribution, which may result in usage difficulty. Therefore, before shipment, the memory is reset according to the method for resetting the threshold voltage of the non-volatile memory of the present invention.

First, the threshold voltage and the threshold voltage uniformity of the non-volatile memory (step 200) are detected. Next, whether or not the threshold voltage and the threshold voltage uniformity of the non-volatile memory are in the range of the setting target value (step 202) is determined. When the threshold voltage and the threshold voltage uniformity of the non-volatile memory are in the range of the setting target value, it indicates that the non-volatile memory need not be reset and can be shipped directly (end directly (step 208)). When the initial threshold voltage and the initial threshold voltage uniformity of the non-volatile memory are not in the range of the setting target value, it indicates that the non-volatile memory needs the resetting step (step 204). In the present invention, the resetting step, for example, includes erasing the non-volatile memory by FN tunneling effect for a period of time until the non-volatile memory is in the erasure saturation state and has the saturation threshold voltage. Then, whether or not the threshold voltage and the threshold voltage uniformity of the non-volatile memory are in the range of the setting target value is determined (step 206). When the threshold voltage and the threshold voltage uniformity of the non-volatile memory are in the range of the setting target value, it indicates that the non-volatile memory need not be reset and can be shipped directly (end directly (step 208)). When the threshold voltage and the threshold voltage uniformity of the non-volatile memory are not in the range of the setting target value, it indicates that the non-volatile memory needs to be reset, and the resetting step (step 204) is performed again until the threshold voltage and the threshold voltage uniformity of the non-volatile memory are in the range of the setting target value.

For example, the target value of the threshold voltage of the non-volatile memory is set to about 3 volts, and the target value of the threshold voltage uniformity is less than or equal to 0.6 (3 times the standard deviation (3σ)). First, the threshold voltage and the threshold voltage uniformity of the non-volatile memory to be shipped are detected. When the detected threshold voltage, for example, is 2.0 volts, and the value of 3 times the standard deviation (3σ) is, for example, 1.16, it indicates that the resetting step is needed. In the resetting step, the erasing bias is set according to the setting target value of the threshold voltage. For example, according to the result of FIG. 3, the erasing bias is set to 16 volts corresponding to the target value of the threshold voltage (3 volts). Then, a voltage of −8 volts is applied to the gate of the non-volatile memory and a voltage of 8 volts is applied to the substrate of the non-volatile memory according to the erasing bias to erase the non-volatile memory by FN tunneling effect for a period of time, for example, 5 seconds, until the non-volatile memory is in the erasure saturation state. Then, the threshold voltage and the threshold voltage uniformity of the non-volatile memory to be shipped are detected once again. If the detected threshold voltage is, for example, 3 volts, and the value of 3 times the standard deviation (3σ) is, for example, less than or equal to 0.6, it indicates that the resetting step is finished and the memory can be shipped. If the detected threshold voltage and the threshold voltage uniformity of the non-volatile memory are not in the range of the setting target value, the above resetting step may be repeated until the threshold voltage and the threshold voltage uniformity of the non-volatile memory are in the range of the setting target value.

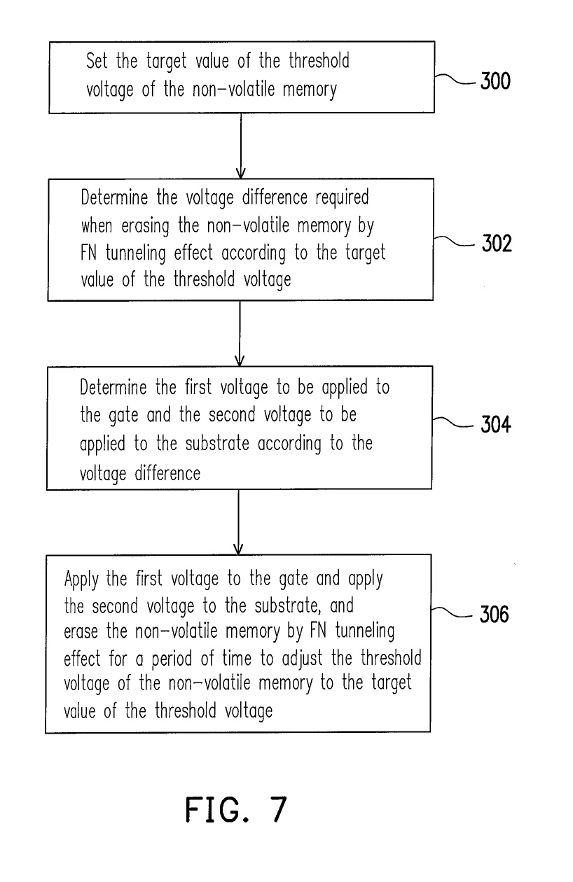

FIG. 7 shows the flow chart of the steps of the method for resetting the threshold voltage of the non-volatile memory according to another embodiment of the present invention.

Referring to FIG. 7, if it is intended to make the reset memory have a setting threshold voltage, the erasing bias is determined according to the desired setting threshold voltage.

First, the target value of the threshold voltage of the non-volatile memory is set (step 300). Then, the voltage difference (erasing bias) required when erasing the non-volatile memory by FN tunneling effect according to the target value of the threshold voltage is determined (step 302). A first voltage to be applied to the gate and a second voltage to be applied to the substrate are determined according to the voltage difference (erasing bias) (step 304). The first voltage is applied to the gate and the second voltage is applied to the substrate, and the non-volatile memory is erased by FN tunneling effect for a period of time, so as to adjust the threshold voltage of the non-volatile memory to the target value of the threshold voltage (step 306).

For example, when it is intended to reset the non-volatile memory, the target value of the threshold voltage of the non-volatile memory is determined according to practical demands, for example, the target value of the threshold voltage is set to 2.4 volts. Then, the voltage difference (erasing bias) required when erasing the non-volatile memory by FN tunneling effect is determined according to the target value (2.4 volts) of the threshold voltage. According to the result of FIG. 3, the erasing bias is set to 14 volts corresponding to the target value (2.4 volts) of the threshold voltage. Then, the voltage to be applied to the gate (for example, −6 volts) and the voltage to be applied to the substrate (for example, 8 volts) are determined according to the voltage difference (erasing bias=14 volts). A voltage of −6 volts is applied to the gate, and a voltage of 8 volts is applied to the substrate, and the non-volatile memory is erased by FN tunneling effect for a period of time until the non-volatile memory is in the erasure saturation state. When the non-volatile memory is in the erasure saturation state, the threshold voltage of the non-volatile memory is the saturation threshold voltage, i.e., equal to the preset target value of the threshold voltage (2.4 volts).

To sum up, the method for resetting the threshold voltage of the non-volatile memory of the present invention is simple and the threshold voltage distribution of the non-volatile memory is reduced easily.

The method for resetting the threshold voltage of the non-volatile memory of the present invention controls the reset target value of the threshold voltage accurately and is capable of solving the problem of the non-uniformity of the threshold voltage of each memory cell resulting from the electrons stored in the charge trapping layer caused by the plasma in the process.

The method for resetting the threshold voltage of the non-volatile memory of the present invention can effectively control the threshold voltage and the threshold voltage distribution of the non-volatile memory without additional, complicated CMOS circuits.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for resetting threshold voltage of a non-volatile memory, suitable for the non-volatile memory having a plurality of memory cells, wherein each of the memory cells is disposed on a substrate and comprises a gate and a charge trapping layer, the method comprising:
erasing the non-volatile memory by FN tunneling effect until erasure saturation such that the memory cells have a saturation threshold voltage.

2. The method of claim 1, wherein the step of erasing the non-volatile memory by FN tunneling effect comprises applying a first voltage to the gates, and applying a second voltage to the substrate, wherein the voltage difference between the second voltage and the first voltage is large enough to induce FN tunneling effect.

3. The method of claim 2, wherein the voltage difference is about 8 volts to 20 volts.

4. The method of claim 2, wherein the first voltage is a negative voltage, and the second voltage is a positive voltage.

5. The method of claim 2, further comprising determining the saturation threshold voltage according to the voltage difference.

6. A method for resetting threshold voltage of a non-volatile memory, suitable for the non-volatile memory having a plurality of memory cells, wherein each of the memory cells is disposed on a substrate and comprises a gate and a charge trapping layer, the method comprising:
(a) detecting threshold voltages and uniformity thereof of the non-volatile memory;
(b) determining whether or not the threshold voltages and the threshold voltage uniformity of the non-volatile memory are in a range of a target value; and
(c) when the threshold voltages and the threshold voltage uniformity of the non-volatile memory are not in the range of the target value, performing a resetting step to erase the non-volatile memory by FN tunneling effect until erasure saturation.

7. The method of claim 6, wherein the step of erasing the non-volatile memory by FN tunneling effect comprises applying a first voltage to the gates, and applying a second voltage to the substrate, wherein the voltage difference between the second voltage and the first voltage is large enough to induce FN tunneling effect.

8. The method of claim 7, wherein the voltage difference is about 8 volts to 20 volts.

9. The method of claim 7, wherein the first voltage is a negative voltage, and the second voltage is a positive voltage.

10. The method of claim 7, wherein the voltage difference is determined according to the target value.

11. The method of claim 7, further comprising repeating the step (b) to step (c) until the threshold voltage and the threshold voltage uniformity of the non-volatile memory are in the range of the target value.

12. A method for resetting threshold voltage of the non-volatile memory, suitable for the non-volatile memory having a plurality of memory cells, wherein each of the memory cells is disposed on a substrate and comprises a gate and a charge trapping layer, the method comprising:
setting a target value of the threshold voltage of the non-volatile memory;
determining a voltage difference required to erase the non-volatile memory by FN tunneling effect to the target value of the threshold voltage;
applying the voltage difference between the substrate and the gates to erase the non-volatile memory by FN tunneling effect until erasure saturation, so as to adjust the threshold voltage of the non-volatile memory to the target value of the threshold voltage.

13. The method of claim 12, wherein the voltage difference is about 8 volts to 20 volts.

14. The method of claim 12, wherein the step of applying the voltage difference between the substrate and the gate comprises:
determining a first voltage to be applied to the gate and a second voltage to be applied to the substrate according to the voltage difference; and
applying the first voltage to the gate, and applying the second voltage to the substrate.

15. The method of claim 14, wherein the first voltage is a negative voltage, and the second voltage is a positive voltage.
